(19) United States
(12) Patent Application Publication
(10) Pub. No.: US 2021/0296518 A1
(43) Pub. Date: Sep. 23, 2021

(54) PHOTOVOLTAIC WITH IMPROVED INSULATION VISIBILITY

(71) Applicant: Garmin Switzerland GmbH, Schaffhausen (CH)

(72) Inventors: Mohamed Bouchoucha, Les Pennes Mirabeau (FR); John M. Kenkel, Kansas City, KS (US); Wen-Yu Wu, New Taipei City (TW); Yu-Hung Lin, New Taipei City (TW)

(21) Appl. No.: 17/204,017

(22) Filed: Mar. 17, 2021

Related U.S. Application Data
(60) Provisional application No. 62/992,523, filed on Mar. 20, 2020.

(51) Int. Cl. H01L 31/0468; H01L 31/0216; H01L 31/0232; G06F 3/044

(52) U.S. Cl. CPC H01L 31/0468; H01L 31/02167; H01L 31/02008; G06F 3/044; H01L 31/02327

(57) ABSTRACT

Systems and methods of generating electrical power for a portable electronic device from a photovoltaic power system are described herein. In some embodiments, a photovoltaic module comprises an interior surface and an exterior surface. The interior photovoltaic cells may be disposed in photovoltaic stripes on the interior surface and exterior photovoltaic cells may be disposed on the exterior surface. Substantially opaque materials are employed to provide a photovoltaic-powered portable electric device with an improved appearance.

### RELATED APPLICATIONS

This non-provisional patent application claims priority benefit, with regard to all common subject matter, of earlier-filed U.S. Provisional Patent Application No. 62/992,523, filed Mar. 20, 2020, and entitled “PHOTOVOLTAIC WITH IMPROVED INSULATION VISIBILITY.” The identified earlier-filed provisional patent application is hereby incorporated by reference in its entirety into the present application.

### BACKGROUND

Conventional wearable electronic devices, like smartwatches, GPS navigation devices, fitness trackers, etc. utilize touchscreens to provide a user interface to users of the electronic devices. Battery life is important for these devices as space is limited. The battery may need to be charged on a regular basis and it can be aggravating for users to stop wearing a device for recharging. Some attempts have been made to equip smartwatches with semitransparent solar panels such as by using a discrete solar cell positioned on top of, or over, the watch's display. In some embodiments, various cell patterns may be disposed on surface or a bezel area of the electronic device. Insulation may be required between the various photovoltaic cells. Typically, the insulation is visible to a user of the electronic device and may distract from the aesthetic design.

### SUMMARY

Embodiments of the invention present a first embodiment directed to a photovoltaic power system for a portable electronic device, the photovoltaic power system comprising at least one photovoltaic cells, each photovoltaic cell comprising a first layer comprising a first conductive electrode, a second layer electrically connected to the first layer and configured to generate an electrical current when exposed to electromagnetic radiation, and a third layer comprising a second conductive electrode, an insulating material disposed proximate each photovoltaic cell of the at least one photovoltaic cells, and a substantially opaque material disposed proximate each photovoltaic cell of the at least one photovoltaic cells for reducing visibility of the insulating material.

A second embodiment is directed to a photovoltaic power system for a portable electronic device, the photovoltaic power system comprising at least one photovoltaic cell, each photovoltaic cell comprising a first layer comprising a transparent conductive oxide, and a second layer electrically connected to the first layer and configured to generate an electrical current when exposed to electromagnetic radiation, and a third layer comprising a conductive electrode, insulating material disposed proximate each photovoltaic cell of the at least one photovoltaic cells, a substantially opaque material for reducing visibility of the insulating material disposed proximate each photovoltaic cell of the at least one photovoltaic cells, a base layer comprising a photovoltaic surface, wherein the at least one photovoltaic cells are disposed along a perimeter of the base layer.

A third embodiment is directed to a photovoltaic power system for a portable electronic device, the photovoltaic power system comprising at least one photovoltaic cell disposed on a photovoltaic surface of a base layer, each photovoltaic cell comprising a first layer comprising a transparent conductive oxide, a second layer electrically connected to the first layer and configured to generate an electric current when exposed to electromagnetic radiation, and a third layer comprising a conductive electrode, insulating material disposed between each photovoltaic cell, a photoresist material for reducing visibility of the insulating material, and a reflective material disposed on a side of the at least one photovoltaic cells opposite the incoming electromagnetic radiation, wherein the at least one photovoltaic cells are disposed along a perimeter of the base layer.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the invention will be apparent from the following detailed description of the embodiments and the accompanying drawing figures.

### BRIEF DESCRIPTION OF THE DRAWING FIGURES

Embodiments of the invention are described in detail below with reference to the attached drawing figures, wherein:

FIGS. 1A-1C, depict an embodiment of photovoltaic cells disposed in an exemplary electronic device;

FIG. 2 depicts photovoltaic module comprising interior and exterior cells;

FIGS. 3-6 depict interior cells with photoresist material;

FIGS. 7A-7B and 8 depict exterior cells with photoresist material;

FIG. 9 depicts an exemplary electronic device for use in connection with various embodiments of the invention;

FIG. 10 depicts an exemplary hardware system for use with embodiments of the invention;

FIG. 11 depicts an exemplary embodiment including various layers of an energy-collecting touchscreen unit;

FIGS. 12 and 13 depict a touch sensor on a front face of the common base layer; and

FIGS. 14 and 15 depict a photovoltaic surface comprising photovoltaic cells on a face of the common base layer of FIGS. 12 and 13.

The drawing figures do not limit the invention to the specific embodiments disclosed and described herein. The drawings are not necessarily to scale, emphasis instead being placed upon clearly illustrating the principles of the invention.

### DETAILED DESCRIPTION

The following detailed description references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the invention. The following detailed description is, therefore, not to be taken in a limiting sense. The scope of the invention is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments but is not necessarily included. Thus, the technology can include a variety of combinations and/or integrations of the embodiments described herein.

In general, embodiments of the invention are directed to systems and methods for presenting photovoltaic cells on portable electronic devices such that a high level of power is generated when a portion of the photovoltaic cells are exposed to electromagnetic radiation.

Because of amorphous silicon content, semi-transparent photovoltaic modules often have a “reddish” appearance from the point of view of an observer. Furthermore, perovskites appear brownish. The “reddish” and “brownish” effect modifies the general color rendering of what is behind the photovoltaic module especially if an electronic display is positioned beneath the photovoltaic module. In configurations where the photovoltaic module is employed on consumer electronic devices, such as smartphones, smartwatches, or other portable electronic devices, black displays may be preferable and not reddish or other colored hues. However, in some embodiments, alternative colors matching insulation material in the electronic device may be used.

In various configurations, a substantially opaque material such as a black photoresist or other opaque or semi-opaque coloring may be applied to one or more portions of the photovoltaic cell to present a darker, or more black, appearance that matches that conventionally found on non-photovoltaic displays. Any opaque or partially opaque material may be utilized between cells to change the desired color presentation of the device. Additionally or alternatively, colored material may be utilized to present any desired coloring for the device (i.e., as opposed to dark black). In embodiments, the material not only provides the desired opacity and coloring, but additionally provides insulation between the cells. That is, the photovoltaic cells' insulation may itself be darkened to present the desired appearance without requiring the addition of new layers to the photovoltaic cell. As described below, such a configuration may be useful for both single-cell and multi-cell photovoltaic designs. In single-cell configurations, the insulation gap between the mono-cell photovoltaic and the corresponding bus bar may be darkened by applying a black photoresist or other darkening material or substantially opaque material to the insulation material. Such a configuration enables more of the photovoltaic (PV) area to be directly exposed to the user (and a light source, such as the sun), including the insulation gap itself.

In multi-cell configurations, insulation lines between the cells may become visible to the user, detracting from the aesthetic appearance of the device. Illustrated below in an example multi-photovoltaic cell configuration for a smartwatch, where the photovoltaic device is intended to be attached above, or otherwise overlay, an electronic smartwatch display. The photovoltaic module includes a dense PV ring, for instance comprising 100% PV coverage, that is substantially opaque and intended to ring the bezel of the smartwatch. Less dense PV coverage, comprising for example lines of photovoltaic material separated between gaps to provide substantial transparency, are overlaid over the center of the display of the smartwatch.

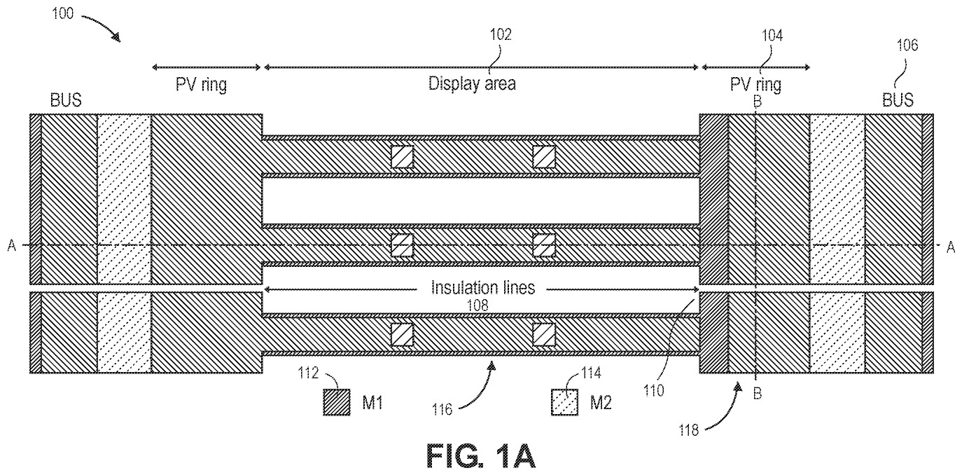

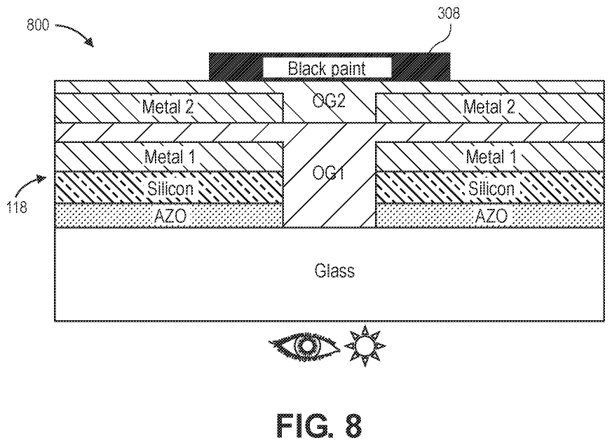

In multi-cell configurations, a photovoltaic power system such as photovoltaic module 100 depicted in a FIGS. 1A-1C, insulation lines between the photovoltaic cells may become visible to the user, detracting from the aesthetic appearance of photovoltaic module 100. Illustrated in FIG. 1A, the exemplary photovoltaic module 100 is configuration for an exemplary smartwatch, where photovoltaic module 100 is intended to be attached above, or otherwise overlay, an electronic smartwatch display. The smartwatch configuration is shown in FIGS. 9-15 and described in detail below. Photovoltaic module 100 includes a dense PV ring, for instance comprising 100% PV coverage, that is substantially opaque and intended to ring the bezel of the smartwatch. Less dense PV coverage, comprising for example lines of photovoltaic material separated between gaps to provide substantial transparency, are overlaid over the center, or face, of the smartwatch's display.

FIGS. 1A-1C depict various cross sections of the interior and the exterior of photovoltaic module 100. Photovoltaic module 100 comprises display area 102, PV ring 104, bus 106, insulation lines 108 on bezel 110, and first metal 112 and second metal 114 that may comprise interior cells 116 and exterior cells 118. Interior cells 116 may be referenced as interior photovoltaic cells and may comprise photovoltaic stipes where the photovoltaic cells are separated into stripes over a display of an electronic device. Exterior cells 118 may be disposed on a bezel outside of the display or substantially encircling the display of the electronic device. In some embodiments, the photovoltaic cells may be connected by insulated vias. Cells of photovoltaic module 100 may be configured as shown in FIGS. 1A-8.

In multi-cell configurations, such as photovoltaic module 100 depicted in a FIGS. 1A-1C, insulation lines 108 between exterior cells 118 may become visible to the user, detracting from the aesthetic appearance of the device. Further, insulation lines between photovoltaic strips of interior cells 116 may also be visible. Illustrated in FIG. 1A, exemplary photovoltaic module 100 is configuration for a smartwatch, where the photovoltaic module 100 is intended to be attached above, or otherwise overlay, an electronic smartwatch display. The smartwatch configuration is shown in FIGS. 9-15 and described in detail below. Photovoltaic module 100 includes dense photovoltaic (PV) ring 104, for instance comprising 100% PV coverage as described above. PV ring 104 may be substantially opaque and intended to ring bezel 208 of the smartwatch. Less dense PV coverage, comprising for example lines of photovoltaic material separated between gaps to provide substantial transparency, are overlaid over the center, or face, of the display of the smartwatch. Interior cells 116 may comprise lines, or stripes, of photovoltaic material that may be arranged in any of the below-described arrangements over the smartwatch display.

FIG. 1B depicts an exemplary embodiment of the structure of photovoltaic module 100 from a cross-section A-A depicted in FIG. 1A. Photovoltaic module 100 may comprise a plurality of interior cells 116 and a plurality of exterior cells 118 and may be any cells described in single or multi-cell designs herein. In some embodiments, the structure of the photovoltaic cells comprises first metal 112, second metal 114, aluminum-doped zinc oxide (AZO) layer 120, silicon layer 122, insulation layer 124, and protection layer 126. In some embodiments, first metal 112 and second metal 114 may be metal electrodes for receiving and conducting the current generated by the absorber layers (e.g. silicon layer 122, and any absorber layers described below). In some embodiments, the second metal may be a reflective metal as described below. The metal layers may comprise any conductive material such as, for example, aluminum, copper, zinc, nickel, graphite, carbon, titanium, brass, silver, gold, platinum and palladium, mixed metal oxide, and any alloy or combination thereof.

In some embodiments, AZO layer 120 may be any general TCO for providing an electrode layer. The description of AZO layer 120 is exemplary. AZO layer 120 may provide a transparent electrode that conducts electric current while providing the benefit of a transparent, or a near transparent, layer. In some embodiments, the absorber layers may be indium tin oxide (ITO), doped zinc oxide, or any other doped oxide, doped oxide, organic material, inorganic material, or polymer as described below in reference to TCO layer 304.

Silicon layer 122 may comprise absorber layers that generate power while being substantially transparent such that a display of the electronic device may be viewed through the photovoltaic cells. The absorber layers may comprise doped metal oxides for generating current when exposed to the electromagnetic radiation. In some embodiments, silicon layer 122 may comprise amorphous silicon, crystalline silicon, Perovskite, organic material, inorganic material, or polymer as described in embodiments herein.

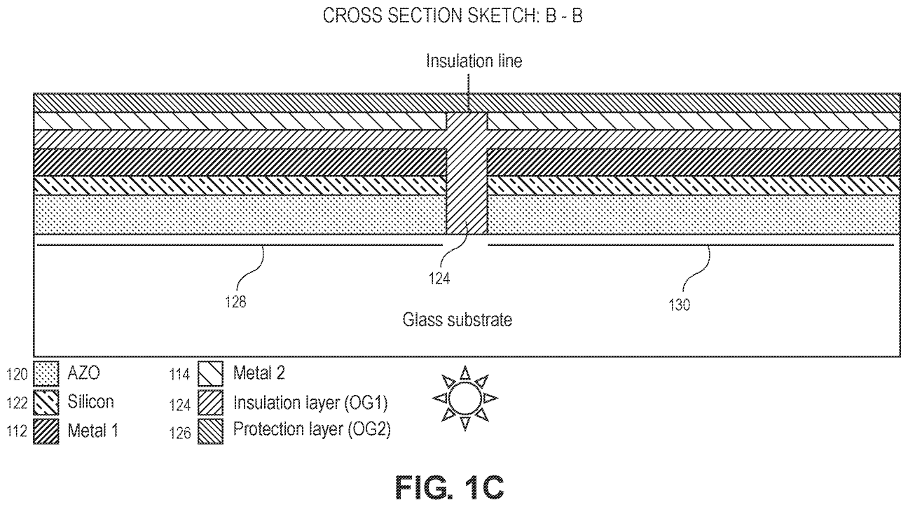

FIG. 1C depicts exterior cells 118 which may be disposed on a bezel portion of the electronic device. FIG. 1C illustrates a cross section B-B of first exterior cell 128 and second exterior cell 130. First exterior cell 128 may be disposed separately from second exterior cell 130 with insulation layer 124 disposed between first exterior cell 128 and second exterior cell 130. In some embodiments, insulation layer 124 and the protection layer 126 may comprise any organic material that has a low conductivity or is non-conductive. In some embodiments, insulation layer 124 may be infused with or comprise a photoresist material. The photoresist material may absorb light such that the insulation lines are not visible to the user. The photoresist material is shown in FIGS. 3-8 and discussed in detail below.

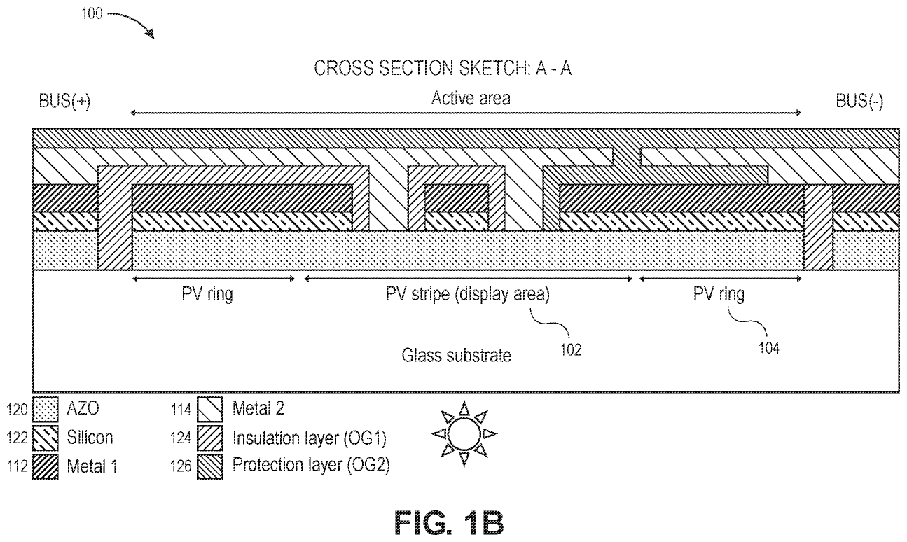

FIG. 2 depicts photovoltaic module 100 including first cell 202 and second cell 204 disposed on face 206 of photovoltaic module 100. Photovoltaic module 100 includes first exterior cell 128 and second exterior cell 130 which may be disposed on bezel 208. Further, first exterior cell 128 and second exterior cell 130 may be independent cells which may have varying photovoltaic density and/or transparency from other cells of the same type or may comprise or otherwise be electrically connected in series with first cell 202 and second cell 204. For example, in smartwatch configurations, exterior cells 118 of photovoltaic module 100 may be opaque while interior cells 116 are desirably less opaque to allow users to view displays or other mechanisms positioned under photovoltaic module 100. As such, first cell 202 and second cell 204 may be disposed as PV stipes along face 206 such that the user may view the display positioned behind first cell 202 and second cell 204.

Insulation lines may exist between the PV stripes of first cell 202 and second cell 204 positioned over the display area and/or between the one or more cells of photovoltaic module 100. These insulation lines may be visible to the user depending on the orientation of photovoltaic module 100 and display characteristics of photovoltaic module 100. Further, insulation lines between first exterior cell 128 and second exterior cell 130 may be visible. To reduce the visibility of the insulation lines, and therefore improve the aesthetic appearance of the photovoltaic module 100 and the electronic device, one or more portions of the photovoltaic insulation may be darkened, for example by replacing the conventional non-black insulation with black matrix or black photoresist material, as illustrated in the below examples. Any non-conductive and electrically insulating material having the desired color and/or opacity may be used by embodiments of the present invention.

FIG. 3 depicts an exemplary sectional view of an embodiment of patterned photoresist material 308 provided on a back side of a second metal 114. A user may peer through glass 310 to a display on an opposite side of interior cells 116 displayed in FIG. 3. In some embodiments, photovoltaic module 100 comprises an absorber layer 302 comprising TCO layer 304, silicon layer 306, first metal 112, and second metal 114. Further, at least one insulating material, insulation layer 124, may be provided between first metal 112 and second metal 114 as well as between each photovoltaic stripe. Photoresist material 308 may be provided on any cell. As depicted in FIG. 3, photoresist material 308 is disposed on a side of interior cells 116 opposite the incoming electromagnetic radiation.

In some embodiments, TCO layer 304 may provide an electrode layer. In some embodiments, TCO layer 304 provides a transparent, or near transparent, layer that may have a higher resistivity than the first electrode layer comprising first metal 112. In some embodiments, TCO layer 304 may be indium tin oxide, doped zinc oxide, or any other doped oxide, organic, inorganic, or polymer that may be used as described in embodiments herein. In some embodiments, TCO layer 304 is fabricated with a silicon layer that may be crystalline silicon or, as depicted, amorphous silicon.

Silicon layer 306 may comprise a material that generates power while being substantially transparent such that a display of the electronic device may be viewed through the photovoltaic cells. Silicon layer 306 may generate current when exposed to electromagnetic radiation. In some embodiments, silicon layer 306 may comprise amorphous silicon, crystalline silicon, perovskites, organic, inorganic, or polymer as described in embodiments herein.

First metal 112 and second metal 114 may be any metal or conductive material that may be used as an electrode or reflecting material. In some embodiments, first metal 112 may be an electrode for receiving and conducting electrical power as described above. In some embodiments, second metal 114 may reflect incoming electromagnetic radiation back into absorber layers 302. Reflecting the electromagnetic radiation through absorber layers 302 a second time provides for a second absorption process for generating power. Therefore, photovoltaic module 100 produces more power.

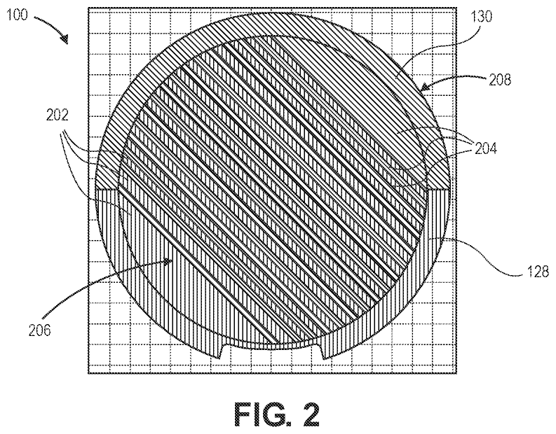

FIG. 4 depicts an exemplary embodiment of photoresist material 308 disposed between first metal 112 and second metal 114 and on the sides of each cell stripe. Insulation lines on the sides of interior cells 116, or photovoltaic stipes, may be obscured by photoresist material 308 covering the sides of absorber layers 302 and first metal 112. Photoresist material 308 may be disposed on the sides of each interior cell 116. Photoresist material 308 may be disposed on the sides of interior cells 116 and space between interior cells 116 may be open (i.e., with no insulation). In this case, photoresist material 308 provides the insulation. Photoresist material 308 may be non-conductive or may be added to the insulation as a dye, paint, or a material that may be incorporated into the insulation material.

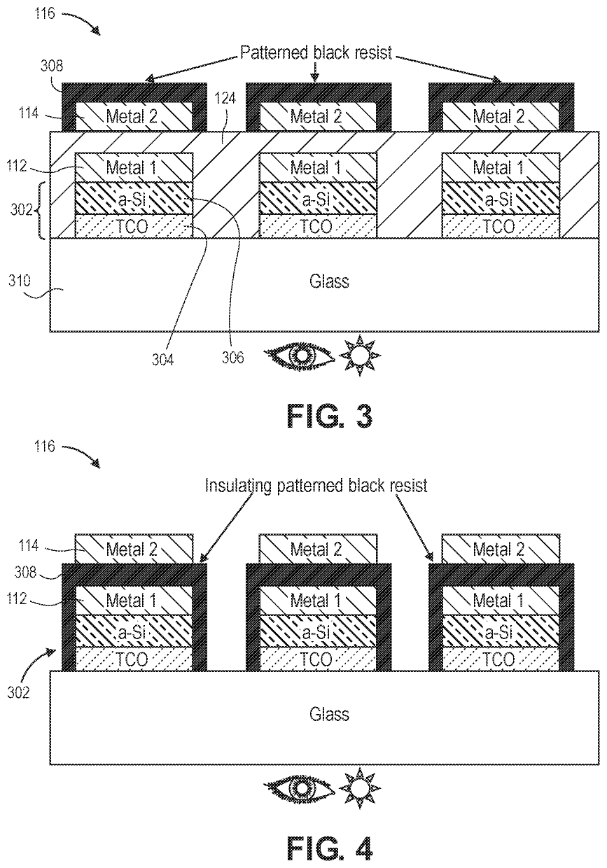

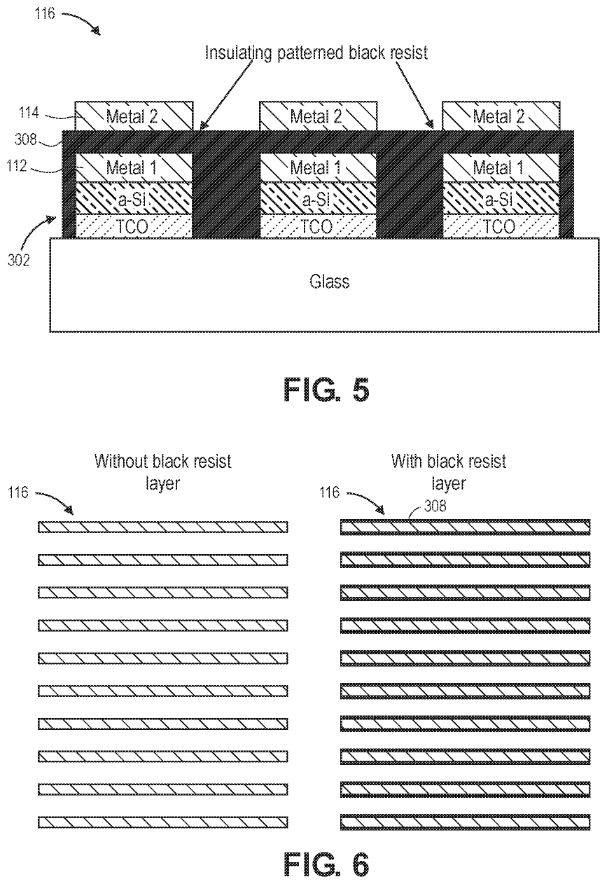

Similarly, in FIG. 5, photoresist material 308 is disposed between first metal 112 and second metal 114 and on the sides of each cell. However, the embodiment depicted in FIG. 5 also presents insulation between interior cells 116 with photoresist material 308. Photoresist material 308 may be the insulating material or, in some embodiments, the insulating material may be infused with photoresist material 308 as described above. Photoresist material 308 may span the entire space between each interior cell 116 as depicted in FIG. 5 or may be a small section just outside of each interior cell 116 as depicted in FIG. 4. Further, FIG. 6 depicts interior cells 116 disposed in lines, or stripes, without photoresist material 308 and with photoresist material 308.

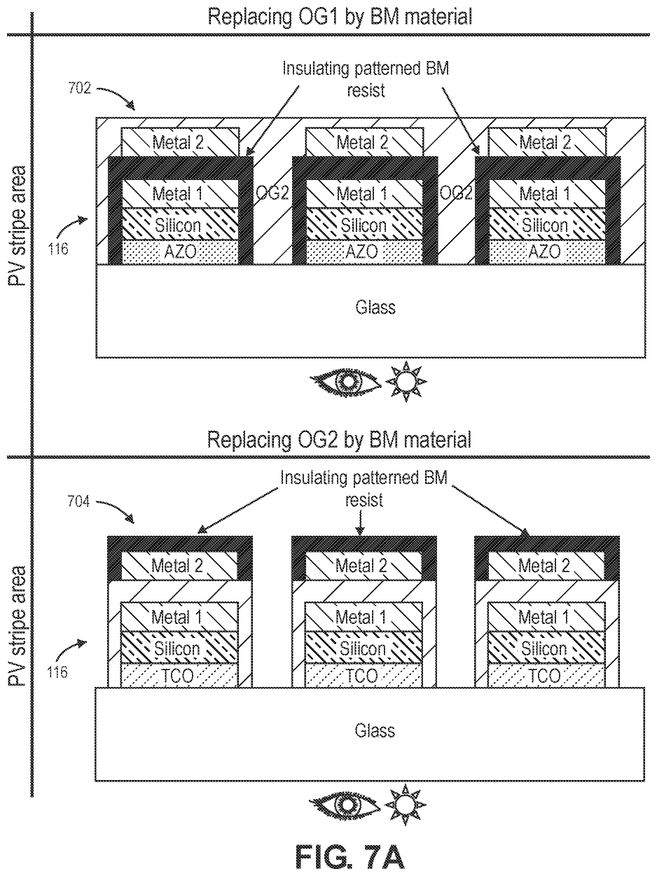

FIG. 7A depicts exemplary embodiments of replacing or integrating organic insulation material, or insulation layer 124, with photoresist material 308. Block 702 and block 704 present embodiments that provide photoresist material 308 on the PV stripe area (e.g., over the display of an electronic device). The PV stripe may be visible by the user when no photoresist material 308 is added. In block 702, photoresist material 308 is added or replaces a first organic insulating material between first metal 112 and second metal 114 and on the sides of interior cells 116 in the PV stripe area. Further, protection layer 126 is shown here as OG2 (organic 2). Adding photoresist material 308 to the sides of interior cells 116 may reduce the visibility. In block 704, photoresist material 308 is also added to interior cells 116 in the PV stripe area. Here, photoresist material 308 is added to a side of second metal 114 opposite of the incoming electromagnetic radiation. The placement of photoresist material 308 may aid in obscuring the insulation material and consequently reducing the visibility of interior cells 116. In some embodiments, such as the exemplary smartwatch embodiment described below in reference to FIGS. 9-15, interior cells 116 may be disposed over a display. Adding photoresist material 308 to interior cells 116 may reduce visibility of interior cells 116 thus decreasing visible distractions from the display.

In FIG. 7B, block 706 and block 708 depict embodiments of photoresist material 308 provided on insulation line 108 for exterior cells 118 disposed around face 206 of photovoltaic module 100. Photoresist material 308 may be disposed between exterior cells 118 as shown in block 706. Photoresist material 308 may replace insulation layer 124 which is represent as organic 1 (OG1). Photoresist material 308 may be added to OG1 as dye or paint or may be infused with the OG1 insulation. In this embodiment, photoresist material 308 is not required with protection layer 126 (e.g., OG2). Therefore, the OG2 is provided between second metal 114 and first metal 112 and between two exterior cells 118 disposed on bezel 208. At block 708, photoresist material 308 is disposed with, or in replace of, OG2. Photoresist material 308 may be disposed in place of OG1 or OG2 and provide reduced visibility of insulation lines 108.

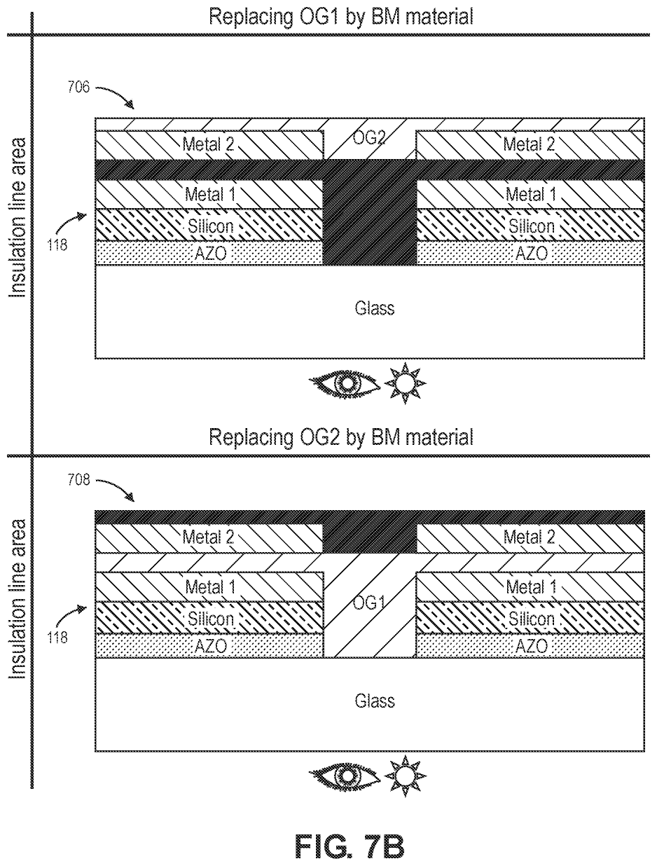

FIG. 8 depicts an exemplary embodiment 800 of providing black paint on a back of OG2 to hide insulation lines 108. The black paint may provide similar function as photoresist material 308 obscuring the visibility of insulation lines 108. In some embodiments, photoresist material 308 may be black paint or may comprise black paint. The black paint may be provided on the back side of insulation line 108 between exterior cells 118 disposed on bezel 208.

### EXEMPLARY ENVIRONMENT

FIG. 9 depicts a perspective view of a mobile electronic device (in this embodiment, smartwatch 900) in accordance with one or more embodiments of the present disclosure. The photovoltaic cells, described below, may be configured to be disposed in, and power, the mobile electronic device. Exemplary smartwatch 900 may be operable to provide fitness information and/or navigation functionality to a user of smartwatch 900. Smartwatch 900 may be configured in a variety of ways. For instance, smartwatch 900 may be configured for use during fitness and/or sporting activities and comprise a cycle computer, a sport watch, a golf computer, a smart phone providing fitness or sporting applications (apps), a handheld GPS device used for hiking, and so forth. However, it is contemplated that the present teachings can be implemented in connection with any mobile electronic device. Thus, the mobile electronic device may also be configured as a portable navigation device (PND), a mobile phone, a handheld portable computer, a tablet computer, a personal digital assistant, a multimedia device, a media player, a game device, combinations thereof, and so forth. In the following description, a referenced component, such as mobile electronic device or specifically, smartwatch 900, may refer to one or more entities, and therefore by convention reference may be made to a single entity (e.g., smartwatch 900) or multiple entities (e.g., smartwatches 900, the plurality of smartwatches 900, and so on) using the same reference number. In some embodiments, the photovoltaic cells may provide power to run all components of the mobile electronic device.

Smartwatch 900 includes housing 902. Housing 902 is configured to house, e.g., substantially enclose, various components of smartwatch 900. Housing 902 may be formed from a lightweight and impact-resistant material such as metal or a metal alloy, plastic, nylon, or combinations thereof, for example. Housing 902 may be formed from a non-conductive material, such a non-metal material, for example. Housing 902 may include one or more gaskets, e.g., a seal, to make it substantially waterproof or water resistant. Housing 902 may include a location for a battery and/or another power source for powering one or more components of smartwatch 900. Housing 902 may be a singular piece or may include a plurality of sections. In embodiments, housing 902 may be formed from a conductive material, such as metal, or a semi-conductive material.

In various embodiments, smartwatch 900 includes viewing area 904. Viewing area 904 may include a liquid crystal display (LCD), a thin film transistor (TFT), a light-emitting diode (LED), a light-emitting polymer (LEP), and/or a polymer light-emitting diode (PLED). However, embodiments are not so limited. In various embodiments, viewing area 904 includes one or more analog or mechanical presentation indicators, such as analog watch hands or mechanical complications or other mechanical gauge or dial indicators. In these embodiments, viewing area 904 is used to display text and/or graphical information. Viewing area 904 may be backlit such that it may be viewed in the dark or other low-light environments. However, embodiments are not so limited. Viewing area 904 may be enclosed by a transparent lens or cover layer that covers and/or protects components of smartwatch 900. Viewing area 904 may be backlit via a backlight such that it may be viewed in the dark or other low-light environments. Viewing area 904 may be provided with a touch screen to receive input (e.g., data, commands, etc.) from a user. For example, a user may operate smartwatch 900 by touching the touch screen and/or by performing gestures on the screen. In some embodiments, the touch screen may be a capacitive touch screen, a resistive touch screen, an infrared touch screen, combinations thereof, and the like. Smartwatch 900 may further include one or more input/output (I/O) devices (e.g., a keypad, buttons, a wireless input device, a thumbwheel input device, a trackstick input device, and so on). The I/O devices may include one or more audio I/O devices, such as a microphone, speakers, and so on.

As noted above, in various embodiments, smartwatch 900 includes one or more mechanical watch hands (e.g., hour hand, minute hand, second hand, and so on) or mechanical complications (date, calendar, dial indicator, and so on). These mechanical watch hands or mechanical complications may be driven by electric motors or other mechanical structures (e.g., spring, wheel, and so on).

Smartwatch 900 may also include a communication module representative of communication functionality to permit smartwatch 900 to send/receive data between different devices (e.g., components/peripherals) and/or over the one or more networks. The communication module may be representative of a variety of communication components and functionality including, but not limited to one or more antennas; a browser; a transmitter and/or receiver; a wireless radio; data ports; software interfaces and drivers; networking interfaces; data processing components; and so forth. Smartwatch 900 may be configured to communicate via one or more networks with a cellular provider and an Internet provider to receive mobile phone service and various content, respectively. Content may represent a variety of different content, examples of which include, but are not limited to map data, which may include route information; web pages; services; music; photographs; video; email service; instant messaging; device drivers; real-time and/or historical weather data; instruction updates; and so forth.

The one or more networks are representative of a variety of different communication pathways and network connections which may be employed, individually or in combinations, to communicate among various components. Thus, the one or more networks may be representative of communication pathways achieved using a single network or multiple networks. Further, the one or more networks are representative of a variety of different types of networks and connections that are contemplated including, but not limited to: The Internet; an intranet; a satellite network; a cellular network; a mobile data network; wired and/or wireless connections; and so forth. Examples of wireless networks include but are not limited to: networks configured for communications according to one or more standard of the Institute of Electrical and Electronics Engineers (IEEE), such as 802.11 or 802.106 (Wi-Max) standards; Wi-Fi standards promulgated by the Wi-Fi Alliance; Bluetooth standards promulgated by the Bluetooth Special Interest Group; and so on. Wired communications are also contemplated such as through universal serial bus (USB), Ethernet, serial connections, and so forth.

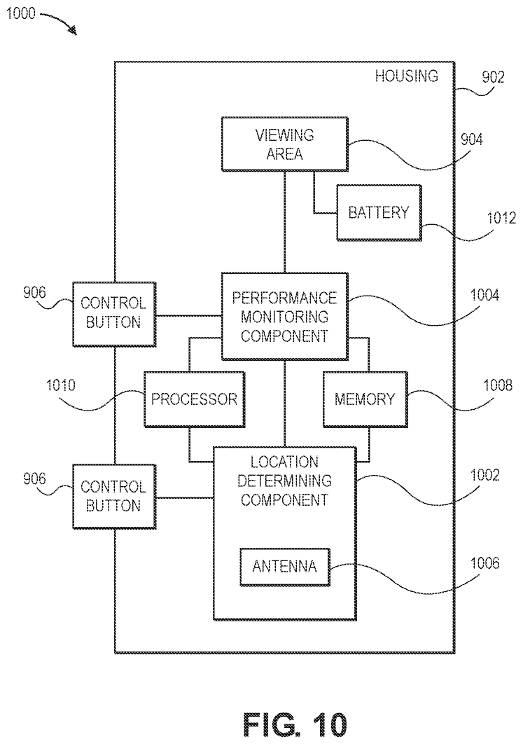

In accordance with one or more embodiments of the present disclosure, the smartwatch 900 includes a control button 906. As illustrated in FIG. 9, control button 906 is associated with, e.g., adjacent to, housing 902. While FIG. 9 illustrates four control buttons 906 associated with housing 902, embodiments are not so limited. For example, smartwatch 900 may include fewer than four control buttons 906, such as one, two, or three control buttons. Additionally, smartwatch 900 may include more than four control buttons 906, such as five, six, or seven, for example. Control button 906 is configured to control a function of smartwatch 900. In various embodiments, regions of the viewing area of smartwatch 900 are covered with a touch sensor as further described below in connection with FIGS. 11-15. In these embodiments, a touchscreen functions as a user interface component to provide input to smartwatch 900, when a user touches various surface regions of the touchscreen associated with the smartwatch 900, which regions are configured to control a function of smartwatch 900.

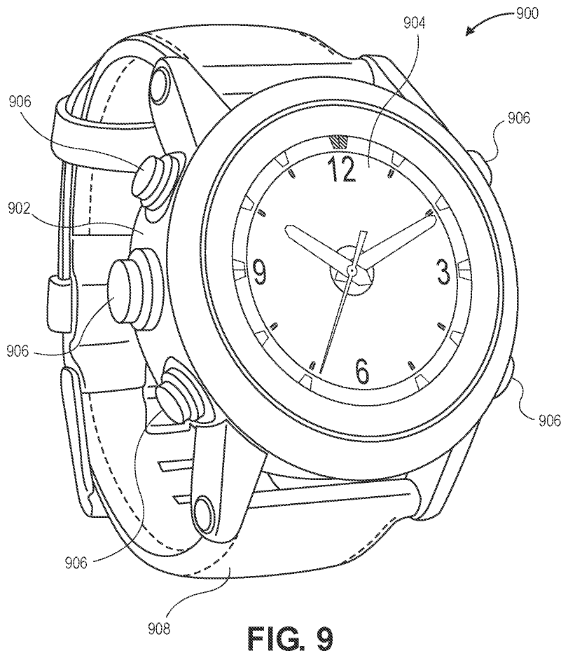

Functions of smartwatch 900 may be associated with location determining component 1002 (FIG. 10) and/or performance monitoring component 1004 (FIG. 10). Functions of smartwatch 900 may include, but are not limited to, displaying a current geographic location of smartwatch 900, mapping a location in viewing area 904, locating a desired location and displaying the desired location on viewing area 904, monitoring a user's heart rate, monitoring a user's speed, monitoring a distance traveled, calculating calories burned, and the like. In embodiments, user input may be provided from movement of housing 902. For example, an accelerometer may be used to identify tap inputs on housing 902 or upward and/or sideways movements of housing 902. In embodiments, user input may be provided from touch inputs identified using various touch sensing technologies, such as resistive touch or capacitive touch interfaces.

In accordance with one or more embodiments of the present disclosure, smartwatch 900 includes strap 908. As illustrated in FIG. 9, strap 908 is associated with, e.g., coupled to, housing 902. For example, strap 908 may be removably secured to housing 902 via attachment of securing elements to corresponding connecting elements. Examples of securing elements and/or connecting elements include, but are not limited to hooks, latches, clamps, snaps, and the like. Strap 908 may be made of a lightweight and resilient thermoplastic elastomer and/or a fabric, for example, such that strap 908 may encircle a portion of a user without discomfort while securing housing 902 to the user. Strap 908 may be configured to attach to various portions of a user, such as a user's leg, waist, wrist, forearm, and/or upper arm.

FIG. 10 shows a block diagram 1000 of the internal components of an exemplary mobile electronic device such as smartwatch 900 of FIG. 9, in accordance with various embodiments of the present disclosure. Housing 902 can include location determining component 1002 positioned within housing 902. For example, location determining component 1002 may include antenna 1006 having a ground plane. The ground plane may be formed by coupling a printed circuit board and/or a conductive cage with antenna 1006. Antenna 1006 and the ground plane may be coupled using solder, connection elements, or combinations thereof.

Location determining component 1002 may be a GPS receiver that is configured to provide geographic location information of smartwatch 900. Location determining component 1002 may be, for example, a GPS receiver such as those provided in various products by GARMIN®. Generally, GPS is a satellite-based radio navigation system capable of determining continuous position, velocity, time, and direction information. Multiple users may simultaneously utilize GPS. GPS incorporates a plurality of GPS satellites that orbit the earth. Based on these orbits, GPS satellites can relay their location to a GPS receiver. For example, upon receiving a GPS signal, e.g., a radio signal, from a GPS satellite, the watch disclosed herein can determine a location of that satellite. The watch can continue scanning for GPS signals until it has acquired a number, e.g., at least three, of different GPS satellite signals. The watch may employ geometrical triangulation, e.g., where the watch utilizes the known GPS satellite positions to determine a position of the watch relative to the GPS satellites. Geographic location information and/or velocity information can be updated, e.g., in real time on a continuous basis, for the watch.

Location determining component 1002 may also be configured to provide a variety of other position-determining functionality. Location determining functionality, for purposes of discussion herein, may relate to a variety of different navigation techniques and other techniques that may be supported by “knowing” one or more positions. For instance, location determining functionality may be employed to provide position/location information, timing information, speed information, and a variety of other navigation-related data. Accordingly, location determining component 1002 may be configured in a variety of ways to perform a wide variety of functions. For example, location determining component 1002 may be configured for outdoor navigation, vehicle navigation, aerial navigation (e.g., for airplanes, helicopters), marine navigation, personal use (e.g., as a part of fitness-related equipment), and so forth. Accordingly, location determining component 1002 may include a variety of devices to determine position using one or more of the techniques previously described.

Location determining component 1002, for instance, may use signal data received via a GPS receiver in combination with map data that is stored in the memory to generate navigation instructions (e.g., turn-by-turn instructions to an input destination or point of interest), show a current position on a map, and so on. Location determining component 1002 may include one or more antennas 1006 to receive signal data as well as to perform other communications, such as communication via one or more networks. Location determining component 1002 may also provide other positioning functionality, such as to determine an average speed, calculate an arrival time, and so on.

Location determining component 1002 may include one or more processors, controllers, and/or other computing devices as well as memory 1008, e.g., for storing information accessed and/or generated by the processors or other computing devices. The processor may be electrically coupled with a printed circuit board and operable to process position determining signals received by antenna 1006. Location determining component 1002, e.g., antenna 1006, is configured to receive position determining signals, such as GPS signals from GPS satellites, to determine a current geographic location of smartwatch 900. Location determining component 1002 may also be configured to calculate a route to a desired location, provide instructions, e.g., directions, to navigate to the desired location, display maps and other information on the display, and to execute other functions, such as, but not limited to, those functions described herein.

Memory 1008 may store cartographic data and routing used by or generated by location determining component 1002. Memory 1008 may be integral with location determining component 1002, stand-alone memory, or a combination of both. Memory 1008 may include, for example, a removable nonvolatile memory card, such as a TransFlash card. Memory 1008 is an example of device-readable storage media that provides storage functionality to store various data associated with the operation of smartwatch 900, such as the software program and code segments mentioned above, or other data to instruct the processor and other elements of smartwatch 900 to perform the techniques described herein. A wide variety of types and combinations of memory may be employed. Memory 1008 may be integral with the processor, stand-alone memory, or a combination of both. Memory 1008 may include, for example, removable and non-removable memory elements such as RAM, ROM, Flash (e.g., SD Card, mini-SD card, micro-SD Card), magnetic, optical, USB memory devices, and so forth.

Antenna 1006, for example, may be configured to receive and/or transmit a signal, such as a GPS signal. Antenna 1006 may be any antenna capable of receiving wireless signals from a remote source, including directional antennas and omnidirectional antennas. Antenna 1006 may include any type of antennas in which the length of the ground plane affects the efficiency of antenna 1006. In accordance with one or more embodiments of the present disclosure, antenna 1006 is an omnidirectional antenna having a ground plane. An omnidirectional antenna may receive and/or transmit in both orthogonal polarizations, depending upon direction. In other words, omnidirectional antennas do not have a predominant direction of reception and/or transmission. Examples of omnidirectional antennas include, but are not limited to, inverted-F antennas (IFAs) and planar inverted-F antennas (PIFAs). In contrast to omnidirectional antennas, directional antennas have a primary lobe of reception and/or transmission over an approximate 70 by 70-degree sector in a direction away from the ground plane. Examples of directional antennas include, but are not limited to, microstrip antennas and patch antennas.

In accordance with one or more embodiments of the present disclosure, antenna 1006 may be an embedded antenna. As used herein, an embedded antenna refers to an antenna that is positioned completely within a device housing. For example, antenna 1006 may be positioned completely within housing 902. In some embodiments, antenna 1006 may be an external antenna with all or a portion of antenna 1006 exposed from housing 902.

As discussed, location determining component 1002 includes antenna 1006. Antenna 1006 may be associated with, e.g., formed on and/or within, an antenna support assembly. Alternatively, antenna 1006 may be positioned on a top portion or one or more side portions of the antenna support assembly.

The printed circuit board may support a number of processors, microprocessors, controllers, microcontrollers, programmable intelligent computers (PIC), field-programmable gate arrays (FPGA), other processing components, other field logic devices, application specific integrated circuits (ASIC), and/or memory 1008 that is configured to access and/or store information that is received or generated by smartwatch 900. Smartwatch 900 may implement one or more software programs to control text and/or graphical information on the display, as discussed herein. As an example, the printed circuit board may support the bottom portion of the antenna support assembly. In some embodiments, the antenna support assembly and antenna 1006 may be positioned in the center of the top surface, bottom surface, or to a side of the of the printed circuit board.

Processor 1010 may provide processing functionality for smartwatch 900 and may include any number of processors, micro-controllers, or other processing systems, and resident or external memory for storing data and other information accessed or generated by smartwatch 900. Processor 1010 may execute one or more software programs that implement the techniques and modules described herein. Processor 1010 is not limited by the materials from which it is formed, or the processing mechanisms employed therein and, as such, may be implemented via semiconductor(s) and/or transistors (e.g., electronic integrated circuits (ICs)), and so forth.

In accordance with one or more embodiments of the present disclosure, functions of smartwatch 900 may be associated with location determining component 1002 and/or the performance monitoring component 1004. For example, location determining component 1002 is configured to receive signals, e.g., position determining signals, such as GPS signals, to determine a position of smartwatch 900 as a function of the signals. Location determining component 1002 may also be configured to calculate a route to a desired location, provide instructions to navigate to the desired location, display maps and/or other information in viewing area 904, to execute other functions described herein, among other things.

Performance monitoring component 1004 may be positioned within housing 902 and be coupled to location determining component 1002 and viewing area 904. Performance monitoring component 1004 may receive information, including, but not limited to geographic location information, from location determining component 1002, to perform a function, such as monitoring performance and/or calculating performance values and/or information related to a watch user's movement, e.g., exercise. The monitoring of the performance and/or the calculating performance values may be based at least in part on the geographic location information. The performance values may include, for example, a user's heart rate, speed, a total distance traveled, total distance goals, speed goals, pace, cadence, and calories burned. These values and/or information may be presented in viewing area 904.

In embodiments, smartwatch 900 includes a user interface, which is storable in memory 1008 and executable by processor 1010. The user interface is representative of functionality to control the display of information and data to the user of smartwatch 900 in viewing area 904. In some implementations, a display module within viewing area 904 may not be integrated into smartwatch 900 and may instead be connected externally using universal serial bus (USB), Ethernet, serial connections, and so forth. The user interface may provide functionality to allow the user to interact with one or more applications of smartwatch 900 by providing inputs via the touch screen and/or the I/O devices. For example, the user interface may cause an application programming interface (API) to be generated to expose functionality to an application to configure the application for display in viewing area 904 or in combination with another display. In embodiments, the API may further expose functionality to configure the application to allow the user to interact with an application by providing inputs via the touch screen and/or the I/O devices. Applications may comprise software, which is storable in memory 1008 and executable by processor 1010, to perform a specific operation or group of operations to furnish functionality to smartwatch 900. Example applications may include fitness application, exercise applications, health applications, diet applications, cellular telephone applications, instant messaging applications, email applications, photograph sharing applications, calendar applications, address book applications, and so forth.

In various embodiments, the user interface may include a browser. The browser enables smartwatch 900 to display and interact with content such as a webpage within the World Wide Web, a webpage provided by a web server in a private network, and so forth. The browser may be configured in a variety of ways. For example, the browser may be configured as an application accessed by the user interface. The browser may be a web browser suitable for use by a full resource device with substantial memory and processor resources (e.g., a smart phone, a personal digital assistant (PDA), etc.). However, in one or more implementations, the browser may be a mobile browser suitable for use by a low-resource device with limited memory and/or processing resources (e.g., a mobile telephone, a portable music device, a transportable entertainment device, wristband, etc.). Such mobile browsers typically conserve battery energy, memory and processor resources, but may offer fewer browser functions than web browsers.

In various embodiments, smartwatch 900 includes an energy storage device such as battery 1012. It is understood that this energy storage device could employ any conventional or later developed energy storage or chemical battery technology, such as a supercapacitor, for example employing electrostatic double-layer capacitance and electrochemical pseudocapacitance. In various embodiments the energy storage device or battery 1012 includes a lithium polymer battery. As explained in connection with FIG. 9, in various embodiments, control button 906 is configured to control a function of smartwatch 900.

In some embodiments, the energy storage device is electrically connected to the photovoltaic cells described herein. The photovoltaic cells may provide power to charge the energy storage device. The photovoltaic cells may be connected directly to the energy storage device or through an intermediate processor for balancing the charge across a plurality of battery cells.

FIG. 11 illustrates the various layers of energy-collecting touchscreen unit 1100 in accordance with an embodiment of the present disclosure. In various embodiments, a thin, substantially transparent lens or cover layer 1102 is provided. A viewing area within touchscreen unit 1100 can be observed through cover layer 1102, while cover layer 1102 protects touchscreen unit 1100 from physical damage. Moreover, in various embodiments extremely robust, scratch-resistant, and substantially transparent materials are employed, such as sapphire glass which is a synthetically produced crystal that is well-suited for use in touchscreens. In various alternate embodiments, cover layer 1102 is made of Gorilla Glass™ from Corning Incorporated from Corning, N.Y.

In various embodiments, common base layer 1104 is provided immediately beneath cover layer 1102. In various embodiments, an air gap between cover layer 1102 and common base layer 1104 is filled with a substantially transparent optical bonding agent. It is understood that cover layer 1102 can be arbitrarily thin, integral to, and forming a part of common base layer 1104. In an embodiment, common base layer 1104 includes touch sensor 1112 that can be used to sense touch at the surface of touchscreen unit 1100. In various embodiments, common base layer 1104 is made of borosilicate glass. In an embodiment, touch sensor 1112 is a capacitive touch panel (“CTP”) made of a transparent conductive material such as indium tin oxide (“ITO”) patterned in an array upon the upper face of common base layer 1104 and, in various embodiments, further processed to facilitate the electrical interconnections.

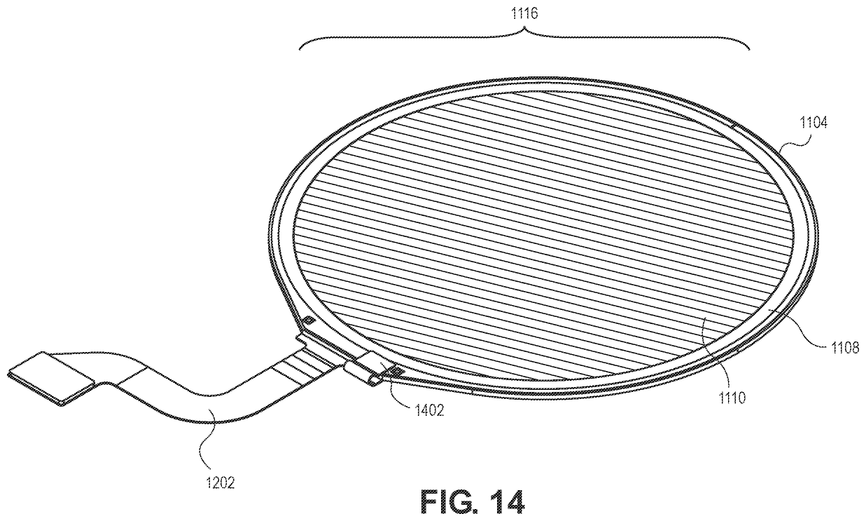

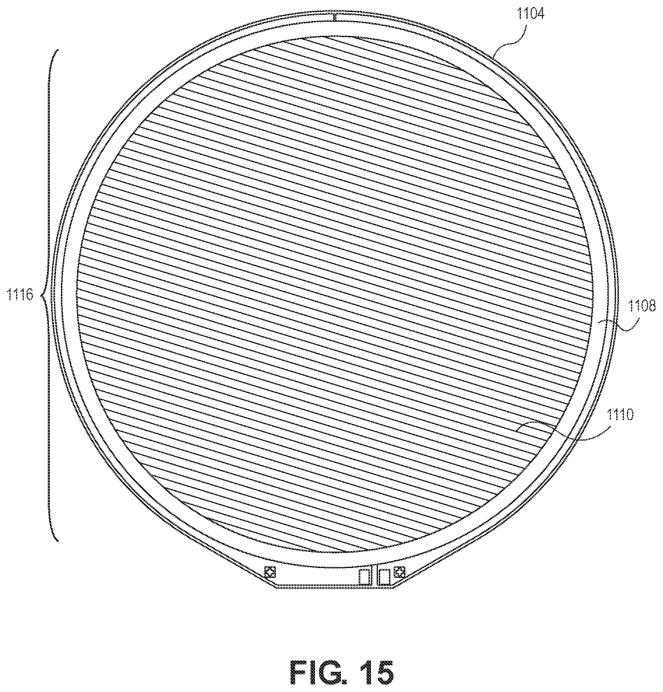

In various embodiments, the bottom face of common base layer 1104 includes materials which provide it with photovoltaic properties. In various embodiments, photovoltaic surface 1116 (as shown in FIGS. 14 and 15) is made up of exterior portion 1108 comprising exterior cells 118 and interior portion 1110 comprising interior cells 116. Photovoltaic surface 1116 is the surface of common base layer 1104 to which interior portion 1110 is applied. In an embodiment, exterior portion 1108 is substantially continuous, meaning that exterior portion 1108 is substantially intact and not etched. By contrast, in various embodiments, interior portion 1110 is photoetched away so that only a minor portion of interior portion 1110 actually covers the surface of common base layer 1104.

In some embodiments, display module 1106 is provided beneath common base layer 1104. In various embodiments, display module 1106 is a liquid crystal pixel array having a pixel pitch of 1026.9 micrometers with each pixel being made up of 9 apertures, 3 apertures for each color sub-pixel. In an embodiment, there is 5 micrometer gap between the apertures. In various embodiments, it is possible to superimpose 10 micrometer wide strips of photovoltaic material such that only 10% of the area of display module 1106 is blocked and the brightness and contrast of the display is only minimally impacted. In an embodiment, the strips of photovoltaic material are superimposed over the columns of the display pixels at a 25-degree tilt angle resulting in a minimal Moire consequence.

In various embodiments, composite photovoltaic surface 1116, which is made up of exterior portion 1108 and interior portion 1110, is circular or substantially congruent to the shape of the face of the smartwatch 900 or other portable electronic device. The photovoltaic surface is further shown in FIGS. 14 and 15 below. In various embodiments, exterior portion 1108 is made up of an annular ring of substantially continuous photovoltaic material along the distal perimeter of the display. Further, interior portion 1110 of photovoltaic material may be dispersed in a pattern across interior portion 1110 of common base layer 1104 so as to minimally obscure viewing of a viewing area within touchscreen unit 1100. Photovoltaic surface 1116 is positioned on the bottom face of common base layer 1104 between display module 1106 and the common base layer 1104. Touch sensor 1112 is deposited upon the upper face of common base layer 1104. In various embodiments, backlight 1114 is provided so display module 1106 is visible in dark or relatively low-light environments.

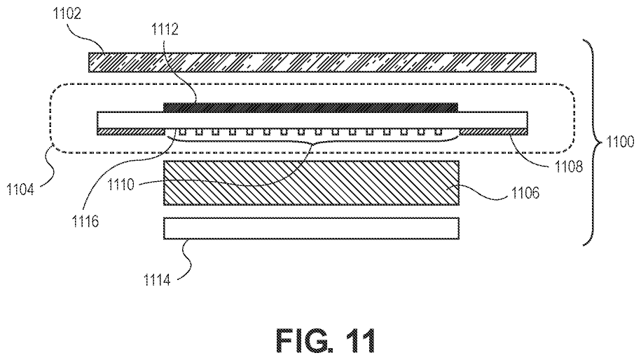

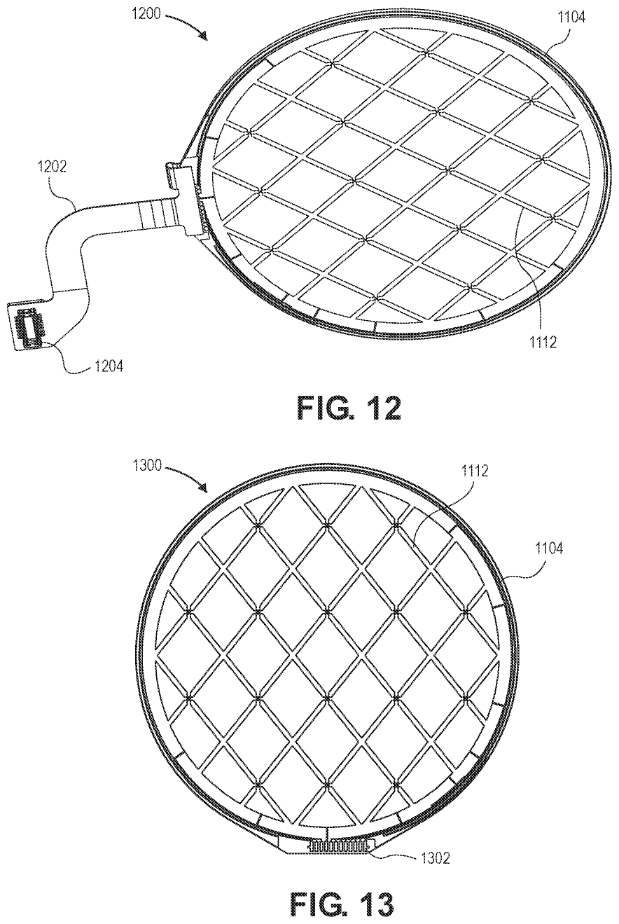

FIGS. 12 and 13 illustrate touch sensor 1112 on a front face of common base layer 1104, in accordance with various embodiments of the present disclosure with flexible printed circuit cable 1202 generally referenced by numeral 1200 and without flexible printed circuit cable 1202 generally reference by numeral 1300. In various embodiments the touchscreen aspect of the portable electronic device is provided as by means of the CTP made up of the ITO array on the upper surface of common base layer 1104 shown in FIG. 12. Additionally, flexible printed circuit cable 1202 is provided with connector 1204 that can be connected to electronics associated with smartwatch 900 such as performance monitoring component 1004 as shown in FIG. 12.

In various embodiments, contact pads made from ITO are provided on the glass surface for electrically interconnecting with flexible printed circuit cable 1202. In various embodiments, contact pads 1302 made of plated copper are provided on flexible printed circuit cable 1202 to facilitate this electrical interconnection. In various embodiments, anisotropic conductive film (“ACF”) material which acts like a conductive glue is provided to bond the glass to flexible printed circuit cable 1202. In various embodiments, the CTP array works by detecting differences, or variations, in capacitance between the ITO areas of touch sensor 1112 of FIGS. 14 and 15. Flexible printed circuit cable 1202 includes connector 1204 in such a way that flexible printed circuit cable 1202 can conveniently be folded under common base layer 1104 and plugged into the electronics of smartwatch 900 before housing 902 (of FIG. 9) is sealed closed. In various embodiments, the CTP of the top face of common base layer 1104 is either affixed to cover layer 1102 or in very close proximity. In order to improve capacitive touch sensitivity, the distance between the ITO touch sensor (the indium tin oxide pattern on the glass) and the touching object being sensed (e.g., a human finger) is minimized. Additionally, sensitivity is enhanced by minimizing a dielectric constant of the materials in that gap. In various embodiments, for a wearable application such as the smartwatch 900, the touch sensor 1112 can sense through air gaps between a lens or similar cover layer 1102. It is understood that touch sensor 1112 operates sub-optimally through layers that are conductive or hold an electrical charge. Where an electrical charge builds up on cover layer 1102, with for example an additional anti-glare coating (not shown), the touch sensor 1112 may fail to operate properly when exposed to direct sunlight, for which reason, consistent with the present teachings, materials are selected that do not hold a substantial electrical charge.

As described above, capacitive touch sensitivity is increased by minimizing the dielectric constant of the combination of materials between the touch sensor 1112 and the object being sensed (typically a finger). By way of reference the dielectric constant of ambient air is approximately 1.0 (relative permittivity), while sapphire is about 10 and glass is about 5, with conductive metals having a dielectric constant that is basically infinite. Accordingly, it is understood that, while glass, such as borosilicate glass, allows for greater touch sensitivity than some harder materials, it lacks the protective qualities of sapphire. Accordingly, a material for cover layer 1102 is selected to provide the most physical protection while still providing adequate touch sensitivity. In this way, a position at which a finger or other capacitive pointing device touches the surface of the cover layer 1102 can be accurately determined by changes in the capacitance measured in the ITO pattern and transmitted to various pins of connector 1204.

FIGS. 14 and 15 illustrate photovoltaic surface 1116 on a front face of common base layer 1104, in accordance with various embodiments of the present disclosure. In various embodiments, photovoltaic surface 1116 is formed from one or more layers of doped amorphous silicon which has the advantages of low cost as well as low toxicity compared to some other photovoltaic materials, but it is understood that other photovoltaic materials may be employed without departing from the present teachings. In various embodiments the pattern of interior portion 1110 of photovoltaic surface 1116 is formed by first depositing a substantially uniform layer or layers of photovoltaic material and then removing desired portions of the material by way of photoetching.

In various embodiments, photovoltaic energy is transmitted through cover layer 1102 and the ITO array of touch sensor 1112 (as well as common base layer 1104) into the photovoltaic layer. The photovoltaic layer is made up of the exterior portion 1108 and interior portion 1110 of photovoltaic surface 1116 comprising the photovoltaic cells. The photovoltaic cells then generate electrical current and, therefore, energy in the photovoltaic layer which is then collected by way of conductors at tab 1402 and through flexible printed circuit cable 1202 to be stored in an energy storage device as described in connection with battery 1012 of FIG. 10. Tab 1402 is bonded to common base layer 1104 with ACF to provide an electrical interconnection to flexible printed circuit cable 1202. In some embodiments, the photoelectric cells provided on the photovoltaic surface may be any of the above-described photovoltaic cell designs.

Although the invention has been described with reference to the embodiments illustrated in the attached drawing figures, it is noted that equivalents may be employed, and substitutions made herein without departing from the scope of the invention as recited in the claims.

Having thus described various embodiments of the invention, what is claimed as new and desired to be protected by Letters Patent includes the following:

1. A photovoltaic power system for a portable electronic device, the photovoltaic power system comprising:
at least one photovoltaic cell comprising:
a first layer comprising a first conductive electrode;
a second layer electrically connected to the first layer and configured to generate an electrical current when exposed to electromagnetic radiation; and
a third layer comprising a second conductive electrode;
an insulating material disposed proximate the at least one photovoltaic cell; and
a substantially opaque material disposed proximate the at least one photovoltaic cell for reducing visibility of the insulating material.

2. The photovoltaic power system of claim 1,
wherein the at least one photovoltaic cell is disposed along a perimeter of a base layer, and the substantially opaque material is photoresist material, and
wherein the first conductive electrode is a transparent conductive oxide.

3. The photovoltaic power system of claim 2,
wherein the base layer further comprises a capacitive touch panel disposed over a photovoltaic surface and comprising an indium tin oxide array for detecting variations in capacitance,
wherein the photovoltaic surface comprises interior photovoltaic cells positioned in side-by-side stripes over a display module, and
wherein the portable electronic device is at least one of wearable and handheld.

4. The photovoltaic power system of claim 3, wherein the substantially opaque material is disposed proximate the interior photovoltaic cells to reduce the visibility of interior insulating material proximate the interior photovoltaic cells.

5. The photovoltaic power system of claim 1,
wherein the insulating material is disposed between each photovoltaic cell of the at least one photovoltaic cells and disposed between each photovoltaic cell and a reflective material, and
wherein the insulating material comprises the substantially opaque material.

6. The photovoltaic power system of claim 1,
further comprising a reflective material disposed on a side of the at least one photovoltaic cell opposite the incoming electromagnetic radiation,
wherein a first portion of the insulating material is disposed between each photovoltaic cell of the at least one photovoltaic cells, and
wherein a second portion of the insulating material is disposed between each photovoltaic cell and the reflective material, and
wherein the second portion of the insulating material comprises the substantially opaque material.

7. The photovoltaic power system of claim 1,
further comprising a reflective material disposed on a side of the at least one photovoltaic cell opposite the incoming electromagnetic radiation,
wherein a first portion of the insulating material is disposed between each photovoltaic cell of the at least one photovoltaic cells,
wherein a second portion of the insulating material is disposed between each photovoltaic cell and the reflective material, and
wherein the first portion of the insulating material comprises the substantially opaque material.

8. A photovoltaic power system for a portable electronic device, the photovoltaic power system comprising:
at least one photovoltaic cell comprising:
a first layer comprising a transparent conductive oxide; and
a second layer electrically connected to the first layer and configured to generate an electrical current when exposed to electromagnetic radiation; and
a third layer comprising a conductive electrode;
insulating material disposed proximate the at least one photovoltaic cells;
a substantially opaque material for reducing visibility of the insulating material disposed proximate the at least one photovoltaic cells;
a base layer comprising a photovoltaic surface,
wherein the at least one photovoltaic cell is disposed along a perimeter of the base layer.

9. The photovoltaic power system of claim 8,
wherein the transparent conductive oxide is aluminum-doped zinc oxide,
wherein the insulating material is disposed between each photovoltaic cell of the at least one photovoltaic cell, and
wherein the insulating material is disposed between each photovoltaic cell and comprises the substantially opaque material.

10. The photovoltaic power system of claim 8,
further comprising a reflective material disposed on a side of the at least one photovoltaic cell opposite the incoming electromagnetic radiation,
wherein a first portion of the insulating material is disposed between each photovoltaic cell of the at least one photovoltaic cell and a second portion of the insulating material is disposed between each photovoltaic cell and the reflective material, and
wherein the second portion comprises the substantially opaque material.

11. The photovoltaic power system of claim 8,
further comprising a reflective material disposed on a side of the at least one photovoltaic cell opposite the incoming electromagnetic radiation,
wherein a first portion of the insulating material is disposed between each photovoltaic cell of the at least one photovoltaic cells and a second portion of the insulating material is disposed between each photovoltaic cell and the reflective material, and
wherein the first portion of the insulating material comprises the substantially opaque material.

12. The photovoltaic power system of claim 8:
wherein the base layer further comprises a capacitive touch panel disposed over the photovoltaic surface and comprising an indium tin oxide array for detecting variations in capacitance, and
wherein the photovoltaic surface comprises interior photovoltaic cells positioned in side-by-side stripes over a display module.

13. The photovoltaic power system device of claim 8, wherein the substantially opaque material is integrated with the insulating material such that the insulating material is at least partially opaque.

14. The photovoltaic power system device of claim 8, wherein the portable electric device is one of a handheld and wearable.

15. A photovoltaic power system for a portable electronic device, the photovoltaic power system comprising:
at least one photovoltaic cell disposed on a photovoltaic surface of a base layer, the at least one photovoltaic cell comprising:
a first layer comprising a transparent conductive oxide;
a second layer electrically connected to the first layer and configured to generate an electric current when exposed to electromagnetic radiation; and
a third layer comprising a conductive electrode;
a photoresist material for reducing visibility of an insulating material; and
a reflective material disposed on a side of the at least one photovoltaic cells opposite the incoming electromagnetic radiation;
wherein the at least one photovoltaic cells is disposed along a perimeter of the base layer.

16. The photovoltaic power system of claim 15,
wherein the base layer is disposed over a display module; and further comprising:
interior photovoltaic cells on the photovoltaic surface; and
interior insulating material disposed on the interior photovoltaic cells.

17. The photovoltaic power system of claim 16, wherein the interior insulating material comprises the photoresist material.

18. The photovoltaic power system of claim 17, further comprising a capacitive touch panel comprising an indium tin oxide array configured to detect a variation in capacitance and transmit a signal indicative of a location of the variation in capacitance.

19. The photovoltaic power system of claim 18, wherein the photovoltaic surface is electrically connected to a flexible printed circuit for providing power to the portable electronic device.

20. The photovoltaic power system of claim 19, wherein the photovoltaic surface powers at least one of a GPS receiver and an accelerometer, and the portable electronic device is at least one of wearable and handheld.
